(19) United States
(12) Patent Application Publication
(10) Pub. No.: US 2022/0285657 A1
(43) Pub. Date: Sep. 8, 2022

(54) ELECTRONIC DEVICE

(71) Applicant: Samsung Display Co., Ltd., Yongin-si (KR)

(72) Inventors: SANG MIN HONG, Cheonan-si (KR); HYUN-GUE SONG, Hwaseong-si (KR); NARI HEO, Hwaseong-si (KR)

(21) Appl. No.: 17/528,541

(22) Filed: Nov. 17, 2021

(30) Foreign Application Priority Data
Mar. 4, 2021 (KR) 10-2021-0029094

(51) Int. Cl. H01L 51/52; G02B 5/00; H01L 27/32; H01L 51/00

(52) U.S. Cl. CPC H01L 51/5284; G02B 5/003; H01L 27/322; H01L 27/323; H01L 27/3244; H01L 51/0097; H01L 51/5253; H01L 51/529; H01L 2251/5338; G06F 3/0446

(57) ABSTRACT

An electronic device includes an optical member including a light blocking layer including a first light emitting opening and a second light emitting opening each defined by adjacent side surfaces, a first color filter overlapping the first light emitting opening, and a second color filter overlapping the second light emitting opening, and a display panel including a first pixel configured to provide the first light emitting opening with light of a first color, and a second pixel configured to provide the second light emitting opening with light of a second color different from the light of the first color, and a surface area of the first light emitting opening is different from a surface area of the second light emitting opening.

### CROSS-REFERENCE TO RELATED APPLICATION

This application claims priority to and the benefit of Korean Patent Application No. 10-2021-0029094, filed on Mar. 4, 2021 in the Korean Intellectual Property Office, the entire content of which is hereby incorporated by reference.

### BACKGROUND

### 1. Field

Aspects of embodiments of the present disclosure relate to an electronic device including an optical member.

### 2. Description of Related Art

In the information society, an electronic device is gaining importance as a visual information delivery medium. Displays included in currently known electronic devices include a liquid crystal display (LCD), a plasma display panel (PDP), an organic light emitting display (OLED), a field effect display (FED), an electrophoretic display (EPD), and the like.

### SUMMARY

According to an aspect of one or more embodiments of the present disclosure, an electronic device having improved color purity at a certain angle is provided.

According to one or more embodiments of the present disclosure, an electronic device includes: an optical member including a light blocking layer including a first light emitting opening and a second light emitting opening each defined by adjacent side surfaces, a first color filter overlapping the first light emitting opening, and a second color filter overlapping the second light emitting opening; and a display panel including a first pixel configured to provide the first light emitting opening with light of a first color, and a second pixel configured to provide the second light emitting opening with light of a second color different from the light of the first color, wherein a surface area of the first light emitting opening is different from a surface area of the second light emitting opening.

In an embodiment, the first light emitting opening may be defined by first side surfaces of a portion of the light blocking layer overlapping the first pixel, and the second light emitting opening may be defined by second side surfaces of a portion of the light blocking layer overlapping the second pixel, wherein a width between the first side surfaces is, in a cross-section, smaller than a width between the second side surfaces.

In an embodiment, the light of the first color may be blue light, and the light of the second color may be any of green light and red light.

In an embodiment, an amount of the light of the first color passing through the first light emitting opening may be less than an amount of the light of the second color passing through the second light emitting opening.

In an embodiment, the light of the first color may be any of green light and red light, and the light of the second color may be blue light.

In an embodiment, the optical member may further include a third light emitting opening defined in the light blocking layer, and a third color filter overlapping the third light emitting opening, and the display panel may further include a third pixel configured to provide light of a third color different from the light of the first color and the light of the second color.

In an embodiment, a surface area of the third light emitting opening may be the same as the surface area of the second light emitting opening and may be larger than the surface area of the first light emitting opening.

In an embodiment, a first width of a portion of the light blocking layer arranged between the second pixel and the third pixel may be, in a cross-section, smaller than a second width of a portion of the light blocking layer arranged between the first pixel and the second pixel.

In an embodiment, the second width may be about 20% to about 30% greater than the first width.

In an embodiment, the electronic device may further include an input sensing panel configured to sense an external input and arranged between the display panel and the optical member.

In an embodiment, the input sensing panel may include a plurality of sensing insulating layers and conductive patterns arranged between the insulating layers, wherein at least one of the conductive patterns is configured as mesh lines.

In an embodiment, the input sensing panel may be directly arranged on the display panel.

In an embodiment, the electronic device may further include: a window on the optical member; and an adhesive layer configured to bond the window to the optical member.

In an embodiment, the electronic device may further include a protection member on a lower portion of the display panel, wherein the protection member includes any of a light blocking pattern, a heat dissipation layer, and a cushion layer.

In an embodiment, the display panel may include a folding area that is foldable about an imaginary folding axis extending in a first direction, and non-folding areas spaced apart from each other in a direction crossing the first direction with the folding area therebetween.

According to one or more embodiments of the present disclosure, an electronic device includes: an optical member including a light blocking layer including first to third light emitting openings, and first to third color filters each overlapping a corresponding light emitting opening of the first to third light emitting openings; and a display panel including first to third pixels each configured to provide light to a corresponding light emitting opening of the first to third light emitting openings, wherein a width between side surfaces of the light blocking layer defining the first light emitting opening is different from a width between side surfaces of the light blocking layer defining each of the second and third light emitting openings.

In an embodiment, the first pixel overlapping the first light emitting opening may be configured to provide blue light.

In an embodiment, a surface area of the first light emitting opening may be smaller than a surface area of each of the second and third light emitting openings.

In an embodiment, a first width of a portion of the light blocking layer arranged between the second pixel and the third pixel may be, in a cross-section, smaller than a second width of a portion of the light blocking layer arranged between the first pixel and the second pixel.

In an embodiment, the second width may be about 20% to about 30% greater than the first width.

### BRIEF DESCRIPTION OF THE DRAWINGS

The accompanying drawings are included to provide a further understanding of the inventive concept, and are incorporated in and constitute a part of this specification. The drawings illustrate some embodiments of the inventive concept and, together with the description, serve to describe principles of the inventive concept. In the drawings:

FIG. 1A is a perspective view of an electronic device, in an unfolded state, according to an embodiment of the inventive concept;

FIG. 1B is a perspective view of an electronic device according to an embodiment of the inventive concept;

FIG. 1C is a plan view of an electronic device, in a folded state, according to an embodiment of the inventive concept;

FIG. 1D a perspective view of an electronic device according to an embodiment of the inventive concept;

FIG. 2A is a cross-sectional view of an electronic device according to an embodiment of the inventive concept;

FIG. 2B is a cross-sectional view of an electronic device according to an embodiment of the inventive concept;

FIG. 2C is a cross-sectional view of an electronic device according to an embodiment of the inventive concept;

FIG. 3 is a plan view of a display panel according to an embodiment of the inventive concept;

FIG. 4 is an equivalent circuit diagram of a pixel according to an embodiment of the inventive concept;

FIG. 5 is a plan view of an input sensing panel according to an embodiment of the inventive concept;

FIG. 6 is a cross-sectional view of an electronic device according to an embodiment of the inventive concept; and

FIG. 7 is a cross-sectional view of an electronic device according to an embodiment of the inventive concept.

### DETAILED DESCRIPTION

It is to be understood that when an element or layer is referred to as being “on,” “connected to,” or “coupled to” another element or layer, it may be directly on, connected to, or coupled to the other element or layer, or one or more intervening elements or layers may be present.

Like reference numerals refer to like elements throughout this specification. In the figures, the thicknesses, ratios, and dimensions of elements may be exaggerated for effective description of the technical contents.

As used herein, the term “and/or” includes any and all combinations of one or more of the associated listed items.

It is to be understood that, although the terms “first,” “second,” etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of the present invention. As used herein, the singular forms, “a,” “an,” and “the” are intended to include the plural forms as well, unless the context clearly indicates otherwise.

Spatially relative terms, such as “beneath,” “below,” “lower,” “above,” and “upper,” may be used herein for ease of description to describe one element or feature's relationship to another element(s) or feature(s) as illustrated in the figures. It is to be understood that the spatially relative terms are intended to encompass different orientations of the device in use or operation in addition to the orientation depicted in the figures.

Unless otherwise defined, all terms including technical and scientific terms used herein have the same meaning as commonly understood by one of ordinary skill in the art to which this disclosure belongs. It is to be further understood that terms, such as those defined in commonly used dictionaries, should be interpreted as having a meaning that is consistent with their meaning in the context of the relevant art and are not to be interpreted in an idealized or overly formal sense unless expressly so defined herein.

It is to be further understood that the terms “include” or “have,” when used in this specification, specify the presence of stated features, integers, steps, operations, elements, components, and/or groups thereof, but do not preclude the presence or addition of one or more other features, integers, steps, operations, elements, components, and/or groups thereof. Herein, the present invention will be described in further detail with reference to the accompanying drawings.

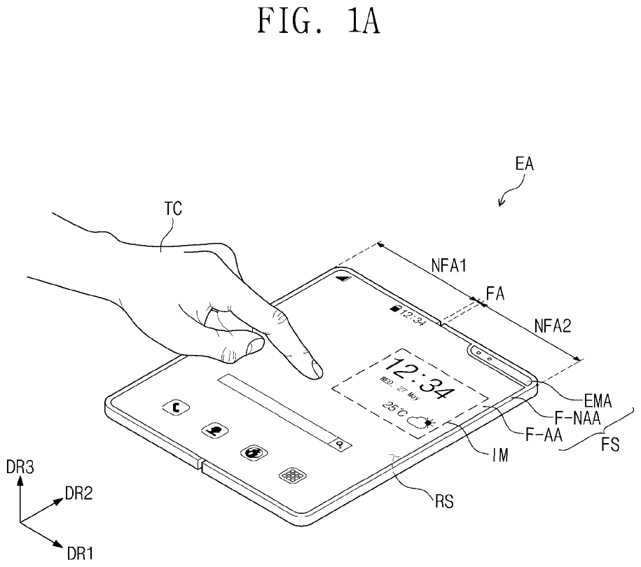

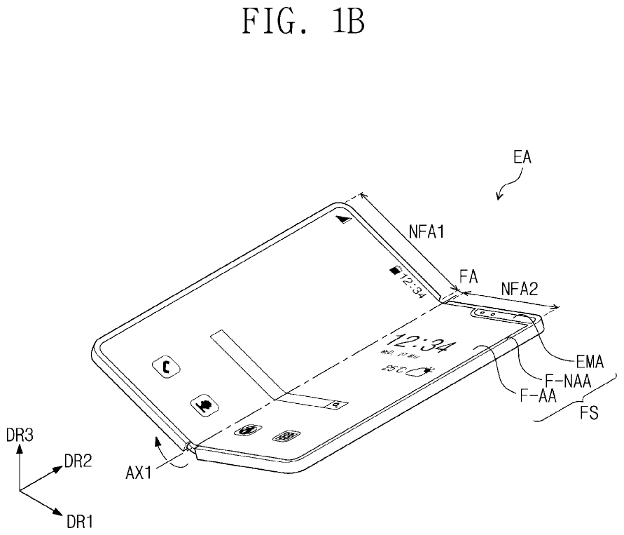

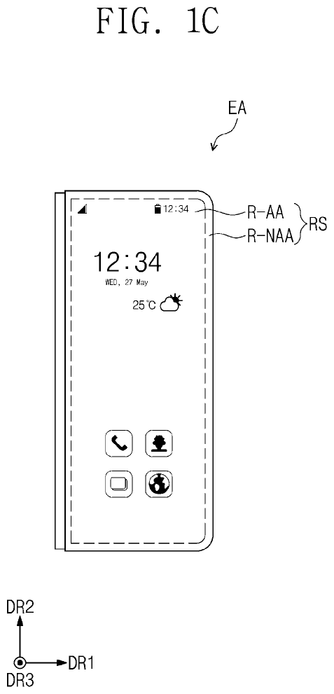

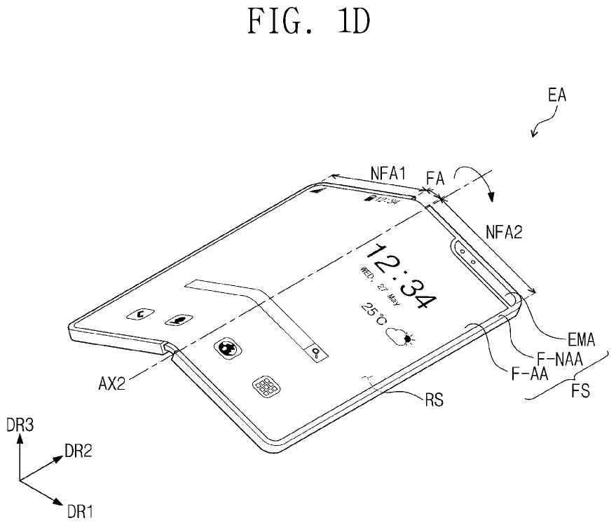

FIG. 1A is a perspective view of an electronic device, in an unfolded state, according to an embodiment of the inventive concept. FIG. 1B is a perspective view of an electronic device according to an embodiment of the inventive concept. FIG. 1C is a plan view of an electronic device, in a folded state, according to an embodiment of the inventive concept. FIG. 1D a perspective view of an electronic device according to an embodiment of the inventive concept.

Referring to FIG. 1A, an electronic device EA may be a device that is activated according to an electrical signal. The electronic device EA may include various embodiments. For example, the electronic device EA may include a tablet, a laptop computer, a general computer, a smart television, or the like. In the present embodiment, the electronic device EA is illustrated, as an example, as a smartphone.

The electronic device EA may display an image IM toward a third direction DR3 on a first display surface FS parallel to each of a first direction DR1 and a second direction DR2. The first display surface FS on which the image IM is displayed may correspond to a front surface of the electronic device EA. The image IM may include a still image, as well as a moving image. In FIG. 1A, an Internet search window and a watch window are illustrated as an example of the image IM.

In the present embodiment, a front surface (or a top surface) and a rear surface (or a bottom surface) of each of components are defined on the basis of a direction in which the image IM is displayed. The front surface and the rear surface may be opposing each other in the third direction DR3, and a normal direction of each of the front surface and the rear surface may be parallel to the third direction DR3.

A separation distance between a front surface and a rear surface in the third direction DR3 of the electronic device EA may correspond to a thickness or height in the third direction DR3 of the electronic device EA. However, the directions indicated by the first to third directions DR1 to DR3 are relative and may be converted into different directions.

The electronic device EA may detect an external input applied from the outside. The external input may include various types of inputs provided from outside of the electronic device EA.

For example, the external input may include an external input (e.g., hovering) that is applied in proximity to the electronic device EA or applied adjacent to the electronic device EA at a distance (e.g., a predetermined distance), in addition to contact by a part of a body such as a user's hand. In addition, the external input may have any of various types, such as force, pressure, temperature, and light.

FIG. 1A illustrates, as an example, an external input through a hand TC of a user. Although not illustrated, the external input may be provided as a pen type. A pen may be stored at a certain location inside or outside the electronic device EA and taken out from the location, and the electronic device EA may provide and receive signals corresponding to the storing and the taking out of the pen.

The electronic device EA according to the present embodiment may include the first display surface FS and a second display surface RS. The first display surface FS may include a first active area F-AA, a first peripheral area F-NAA, and an electronic module area EMA. The second display surface RS may be defined as a surface opposing at least a portion of the first display surface FS.

The first active area F-AA may be an area that is activated according to an electrical signal. The first active area F-AA is an area in which the image IM is displayed and which is capable of sensing various types of external inputs. The first peripheral area F-NAA is adjacent to the first active area F-AA. The first peripheral area F-NAA may have a color (e.g., a predetermined color). In an embodiment, the first peripheral area F-NAA may surround the first active area F-AA. Accordingly, the shape of the first active area F-AA may be substantially defined by the first peripheral area F-NAA.

However, this is illustrated by way of example, and, in another embodiment, for example, the first peripheral area F-NAA may be disposed adjacent to only one side of the first active area F-AA, or may be omitted.

A variety of electronic modules may be disposed in the electronic module area EMA. For example, the electronic modules may include one or more of a camera, a speaker, a light sensor, and a heat sensor. The electronic module area EMA may sense an external subject received through the display surfaces FS and RS or provide a sound signal, such as a voice, to the outside through the display surfaces FS and RS. The electronic modules may include a plurality of components and are not limited to any one embodiment.

In an embodiment, the electronic module area EMA may be surrounded by the first active area F-AA and the first peripheral area F-NAA. However, embodiments are not limited thereto, and, in another embodiment, for example, the electronic module area EMA may be disposed inside the first active area F-AA but is not limited to any particular embodiment.

The electronic device EA according to the present embodiment may include at least one folding area FA and a plurality of non-folding areas NFA1 and NFA2 extending from the folding area FA. The non-folding areas NFA1 and NFA2 may be disposed to be spaced apart from each other with the folding area FA interposed therebetween.

Referring to FIG. 1B, the electronic device EA according to an embodiment includes an imaginary first folding axis AX1 extending in the second direction DR2. The first folding axis AX1 may extend in the second direction DR2 on the first display surface FS. In the present embodiment, the non-folding areas NFA1 and NFA2 may extend from the folding area FA with the folding area FA interposed therebetween.

For example, a first non-folding area NFA1 may extend from a first side of the folding area FA in the first direction DR1, and a second non-folding area NFA2 may extend from another side of the folding area FA in the first direction DR1.

The state of the electronic device EA may be changed to an in-folded state in which, by folding the electronic device EA about the first folding axis AX1, a first area overlapping the first non-folding area NFA1 among the first display surface FS faces another area overlapping the second non-folding area NFA2 thereamong.

Referring to FIG. 1C, a user may view the second display surface RS of the electronic device EA according to an embodiment when the electronic device EA is in the in-folded state. In this case, the second display surface RS may include a second active area R-AA displaying an image. The second active area R-AA may be an area that is activated according to an electrical signal. The second active area R-AA is an area in which an image is displayed and which is capable of sensing various types of external inputs.

A second peripheral area R-NAA is adjacent to the second active area R-AA. The second peripheral area R-NAA may have a color (e.g., a predetermined color). In an embodiment, the second peripheral area R-NAA may surround the second active area R-AA. In addition, although not illustrated, an electronic module area in which electronic modules including various components are disposed may be further included in the second display surface RS, and is not limited to any particular embodiment.

Referring to FIG. 1D, the electronic device EA according to an embodiment includes an imaginary second folding axis AX2 extending in the second direction DR2. The second folding axis AX2 may extend in the second direction DR2 on the second display surface RS.

The state of the electronic device EA may be changed to an out-folded state in which, by folding the electronic device EA about the second folding axis AX2, a first area overlapping the first non-folding area NFA1 among the second display surface RS faces another area overlapping the second non-folding area NFA2 thereamong.

However, the electronic device EA is not limited thereto and may be folded such that, by folding the electronic device EA about a plurality of folding axes, a portion of the first display surface FS and a portion of the second display surface RS face each other, and the number of the folding axes and the number of non-folding areas according thereto are not limited to any particular embodiment.

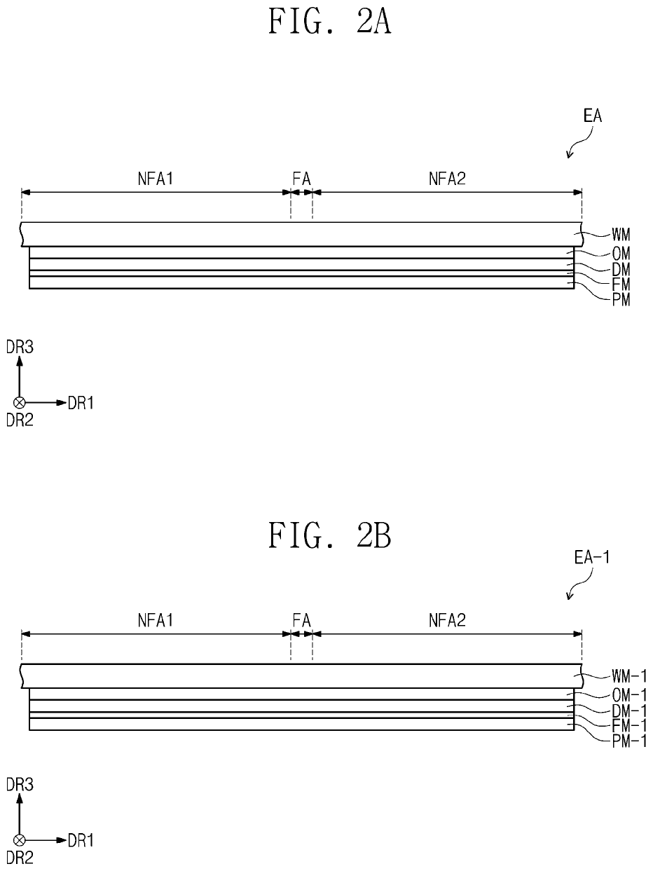

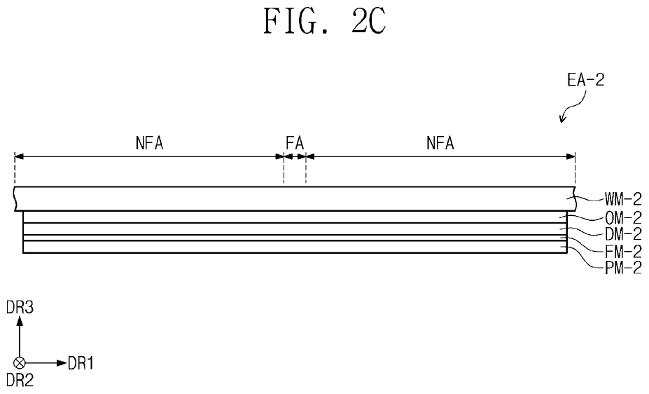

FIG. 2A is a cross-sectional view of an electronic device according to an embodiment of the inventive concept. FIG. 2B is a cross-sectional view of an electronic device according to an embodiment of the inventive concept. FIG. 2C is a cross-sectional view of an electronic device according to an embodiment of the inventive concept.

Referring to FIG. 2A, the electronic device EA according to an embodiment may include a window WM, an optical member OM, a display module DM, a lower film FM, and a protection member PM.

The window WM may include a material having high light transmittance. For example, the window WM may include a glass substrate, a sapphire substrate, or a plastic film. The window WM may have a multilayer structure or a single-layer structure.

For example, the window WM may have a laminated structure of a plurality of plastic films bonded by an adhesive or may have a laminated structure of a glass substrate and a plastic film bonded by an adhesive. Although not illustrated, functional layers for protecting the window WM may be further included on the window WM. For example, the functional layers may include at least one of an anti-fingerprint layer or an impact absorbing layer, and are not limited to any particular embodiment.

The optical member OM is disposed on a lower portion of the window WM. The optical member OM may reduce reflectance of the display module DM for external light incident on the display module DM. For example, the optical member OM may include at least one of an anti-reflection film, a color filter, or a gray filter.

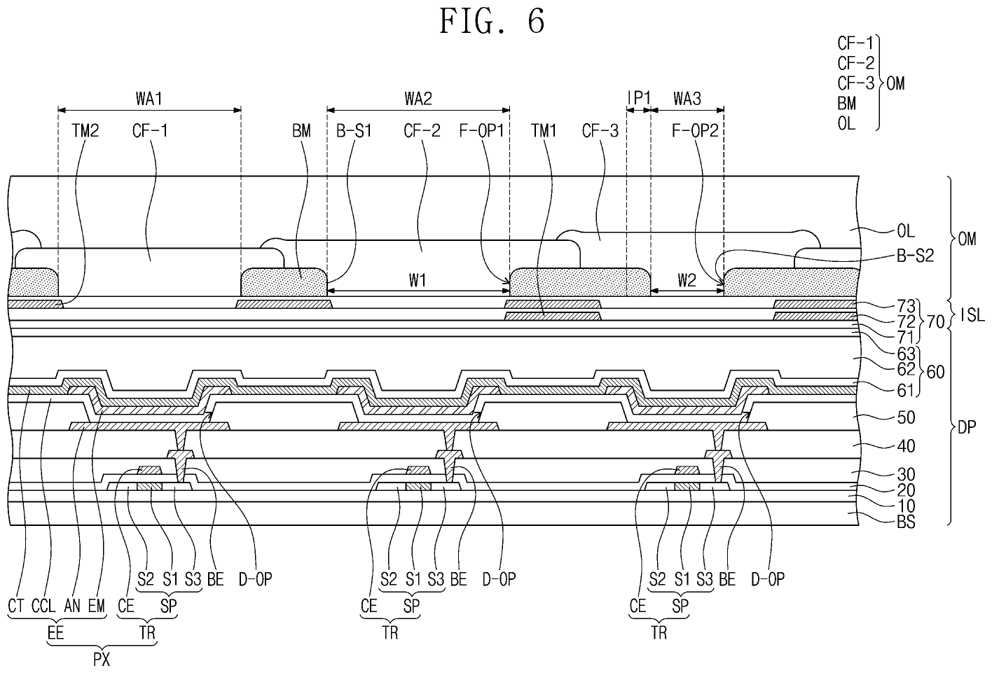

The optical member OM may include a light blocking layer BM (see FIG. 6) that provides an emission amount of light provided from the display module DM and a plurality of color filters CF-1, CF-2, and CF-3 (see FIG. 6). A description thereof will be provided later.

The lower film FM is disposed on a lower portion of the display module DM. The lower film FM may reduce stress applied to the display module DM when the electronic device EA is folded. In addition, the lower film FM may prevent or substantially prevent external moisture from permeating into the display module DM and may absorb an external shock.

The lower film FM may include a plastic film as a base layer. The lower film FM may include a plastic film including any selected from a group consisting of polyethersulfone (PES), polyacrylate, polyetherimide (PEI), polyethylene naphthalate (PEN), polyethylene terephthalate (PET), polyphenylene sulfide (PPS), polyarylate, polyimide (PI), polycarbonate (PC), poly(arylene ethersulfone), and a combination thereof.

A material constituting the lower film FM is not limited to plastic films and may include an organic/inorganic composite material. In an embodiment, the lower film FM may include a porous organic layer and an inorganic material filled in pores of the organic layer.

The lower film FM may further include a functional layer formed on the plastic film. The functional layer may include a resin layer. The functional layer may be formed by a coating method.

The protection member PM is disposed on a lower portion of the display module DM. The protection member PM may include at least one functional layer protecting the display module DM. For example, the protection member PM may include any of a light blocking pattern, a heat dissipation layer, a cushion layer, and a plurality of adhesive layers.

The light blocking pattern may alleviate a problem that components disposed in the display module DM are vaguely seen on the window WM through the active areas F-AA and R-AA. Although not illustrated, a binder and a plurality of pigment particles dispersed therein may be included in the light blocking pattern. The pigment particles may include carbon black or the like. The electronic device EA according to an embodiment may have an effect of improving a light shielding property by including the protection member PM including the light blocking pattern.

The heat dissipation layer may effectively dissipate heat generated from the display module DM. The heat dissipation layer may include at least one of graphite, copper (Cu), or aluminum (Al) having good heat dissipation properties, but is not limited thereto. The heat dissipation layer may not only improve heat dissipation properties but may also have electromagnetic wave shielding properties or electromagnetic wave absorption properties.

The cushion layer may be formed of synthetic resin foam. The cushion layer may include a matrix and a plurality of voids. The cushion layer may have elasticity and a porous structure.

The matrix may include a flexible material. The matrix may include synthetic resin. For example, the matrix may include at least one of acrylonitrile butadiene styrene copolymer (ABS), polyurethane (PU), polyethylene (PE), ethylene vinyl acetate (EVA), or polyvinyl chloride (PVC).

The plurality of voids easily absorb impact applied to the cushion layer. The plurality of voids may be defined as the cushion layer has the porous structure.

However, embodiments are not limited thereto. For example, at least one of the light blocking pattern, the heat dissipation layer, or the cushion layer may be omitted, and the plurality of layers may be provided as a single layer, and an embodiment of the inventive concept is not limited to any particular embodiment.

Although not illustrated, in an embodiment, the components included in the electronic device EA may be bonded together by an adhesive layer disposed between the components. Herein, the adhesive layer to be described in an embodiment of the inventive concept may be an optically clear adhesive (OCA) film, an optically clear resin (OCR), or a pressure sensitive adhesive (PSA) film. Further, the adhesive layer may include a photocurable adhesive material or a thermosetting adhesive material, and a material thereof is not particularly limited.

Referring to FIG. 2B, an electronic device EA-1 according to an embodiment may include a window WM-1, an optical member OM-1, a display module DM-1, a lower film FM-1, and a protection member PM-1. The components included in the electronic device EA-1 of FIG. 2B may respectively be the same as the components included in the electronic device EA described with reference to FIG. 2A, and differences according to the laminating order will be described.

The electronic device EA-1 according to the present embodiment may have a structure in which the protection member PM-1, the lower film FM-1, the display module DM-1, the optical member OM-1, and the window WM-1 are sequentially laminated in the third direction DR3.

Referring to FIG. 2C, an electronic device EA-2 according to an embodiment may include a window WM-2, an optical member OM-2, a display module DM-2, a lower film FM-2, and a protection member PM-2. The components included in the electronic device EA-2 of FIG. 2C may respectively be the same as the components included in the electronic device EA described with reference to FIG. 2A, and differences according to the laminating order will be described.

The electronic device EA-2 according to the present embodiment may have a structure in which the protection member PM-2, the lower film FM-2, the display module DM-2, the optical member OM-2, and the window WM-2 are sequentially laminated in the third direction DR3.

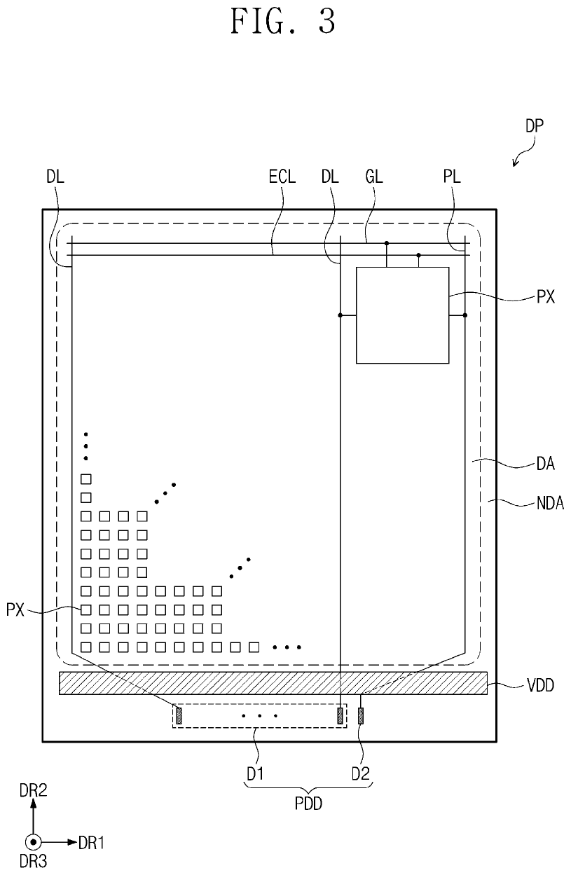

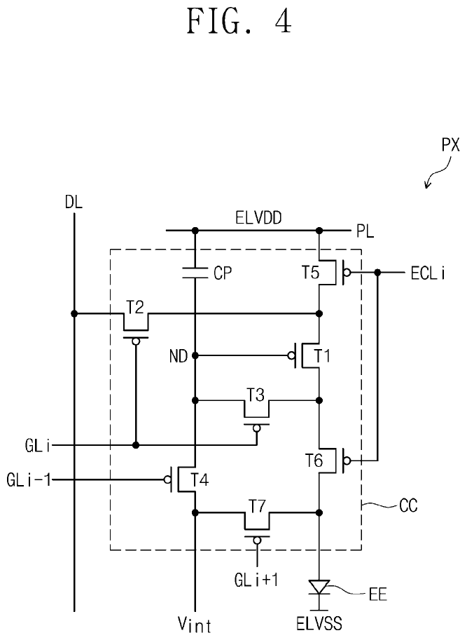

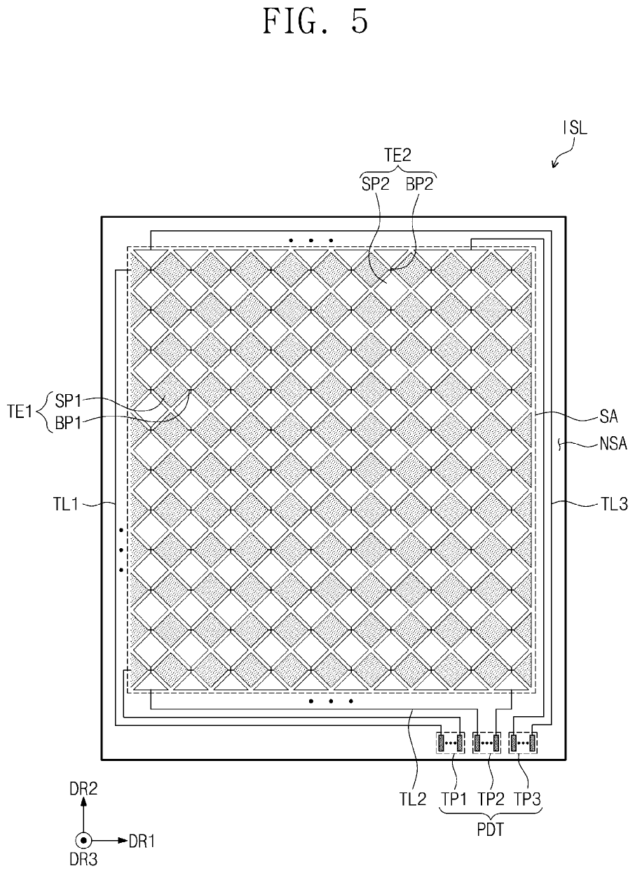

FIG. 3 is a plan view of a display panel according to an embodiment of the inventive concept. FIG. 4 is an equivalent circuit diagram of a pixel according to an embodiment of the inventive concept. FIG. 5 is a plan view of an input sensing panel according to an embodiment of the inventive concept.

Referring to FIG. 3, a display panel DP may include a plurality of pixels PX, a plurality of signal lines GL, DL, PL, and ECL, and a plurality of display pads PDD.

A display area DA of the display panel DP may be an area in which the image IM is displayed, and a non-display area NDA may be an area in which a driving circuit, a driving line, or the like is disposed. The display area DA may overlap at least a portion of the active areas F-AA and R-AA of the electronic device EA. In addition, the non-display area NDA may overlap the peripheral areas F-NAA and R-NAA of the electronic device EA.

In an embodiment, the display panel DP may be any of a liquid crystal display panel, an electrophoretic display panel, a microelectromechanical system (MEMS) display panel, an electrowetting display panel, an organic light emitting display panel. and an inorganic light emitting display panel, and the display panel DP is not particularly limited.

The plurality of signal lines GL, DL, PL, and ECL are connected to the pixels PX to transmit electrical signals to the pixels PX. Among the signal lines included in the display panel DP, a scan line GL, a data line DL, a power line PL, and an emission control line ECL are illustrated as an example. Each of the scan line GL, the data line DL, the power line PL, and the emission control line ECL may be provided in plural. However, this is illustrated by way of example, and the signal lines GL, DL, PL, and ECL may further include an initialization voltage line and are not limited to any particular embodiment.

The pixels PX may be arranged to be spaced apart from each other in the first direction DR1 and the second direction DR2 and thus may have a matrix shape when viewed in a plane. However, the pixels PX are not limited thereto and, in an embodiment, may be arranged in a Pentile form having a diamond arrangement structure.

FIG. 4 illustrates, as an example, an enlarged signal circuit diagram of a pixel PX of the plurality of pixels. The pixel PX connected to an i-th scan line GLi and an i-th emission control line ECLi is illustrated, as an example, in FIG. 4.

The pixel PX may include a light emitting element EE and a pixel circuit CC. The pixel circuit CC may include a plurality of transistors T1 to T7 and a capacitor CP. In an embodiment, the plurality of transistors T1 to T7 may be formed through a low temperature polycrystalline silicon (LTPS) process or a low temperature polycrystalline oxide (LTPO) process.

The pixel circuit CC controls an amount of current flowing through the light emitting element EE in response to a data signal. The light emitting element EE may emit light of a luminance (e.g., a predetermined luminance) corresponding to the amount of current provided from the pixel circuit CC. To this end, a voltage level of a first power source ELVDD may be set higher than a voltage level of a second power source ELVSS. In an embodiment, the light emitting element EE may include an organic light emitting element or a quantum dot light emitting element.

Each of the plurality of transistors T1 to T7 may include an input electrode (or a source electrode), an output electrode (or a drain electrode), and a control electrode (or a gate electrode). In this specification, for convenience, one of the input electrode and the output electrode may be referred to as a first electrode, and the other thereof may be referred to as a second electrode.

The first electrode of a first transistor T1 is connected to the first power source ELVDD via a fifth transistor T5, and the second electrode the first transistor T1 is connected to an anode of the light emitting element EE via a sixth transistor T6. The first transistor T1 may be referred to as a driving transistor in this specification.

The first transistor T1 controls the amount of current flowing through the light emitting element EE in response to a voltage applied to the control electrode of the first transistor T1.

A second transistor T2 is connected between the data line DL and the first electrode of the first transistor T1. The control electrode of the second transistor T2 is connected to the i-th scan line GLi. The second transistor T2 is turned on when an i-th scan signal is provided through the i-th scan line GLi, such that the second transistor T2 electrically connects the data line DL to the first electrode of the first transistor T1.

A third transistor T3 is connected between the second electrode of the first transistor T1 and the control electrode of the first transistor T1. The control electrode of the third transistor T3 is connected to the i-th scan line GLi. The third transistor T3 is turned on when the i-th scan signal is provided through the i-th scan line GLi, such that the third transistor T3 electrically connects the second electrode of the first transistor T1 to the control electrode of the first transistor T1. Accordingly, the first transistor T1 is connected in the form of a diode when the third transistor T3 is turned on.

A fourth transistor T4 is connected between a node ND and an initialization power generating unit (not illustrated). The control electrode of the fourth transistor T4 is connected to an (i−1)-th scan line GLi−1. The fourth transistor T4 is turned on when an (i−1)-th scan signal is provided through the (i−1)-th scan line GLi−1, such that the fourth transistor T4 provides an initialization voltage Vint to the node ND.

The fifth transistor T5 is connected between the power line PL and the first electrode of the first transistor T1. The control electrode of the fifth transistor T5 is connected to the i-th emission control line ECLi.

The sixth transistor T6 is connected between the second electrode of the first transistor T1 and the anode of the light emitting element EE. The control electrode of the sixth transistor T6 is connected to the i-th emission control line ECLi.

A seventh transistor T7 is connected between the initialization power generating unit (not illustrated) and the anode of the light emitting element EE. The control electrode of the seventh transistor T7 is connected to an (i+1)-th scan line GLi+1. The seventh transistor T7 is turned on when an (i+1)-th scan signal is provided through the (i+1)-th scan line GLi+1, such that the seventh transistor T7 provides the initialization voltage Vint to the anode of the light emitting element EE.

The seventh transistor T7 may improve black display capability of the pixel PX. Specifically, when the seventh transistor T7 is turned on, a parasitic capacitor (not illustrated) of the light emitting element EE is discharged. Then, when black luminance is implemented, the light emitting element EE does not emit light due to a leakage current from the first transistor T1, and, accordingly, the black display capability may be improved.

In addition, although the control electrode of the seventh transistor T7 is illustrated to be connected to the (i+1)-th scan line GLi+1 in FIG. 4, an embodiment of the inventive concept is not limited thereto. In another embodiment of the inventive concept, a control electrode of a seventh transistor T7 may be connected to an i-th scan line GLi or an (i−1)-th scan line GLi−1.

The capacitor CP is disposed between the power line PL and the node ND. The capacitor CP stores a voltage corresponding to the data signal. When the fifth transistor T5 and the sixth transistor T6 are turned on, an amount of current flowing through the first transistor T1 may be determined depending on the voltage stored in the capacitor CP.

In embodiments of the inventive concept, an equivalent circuit of the pixel PX is not limited to the equivalent circuit illustrated in FIG. 4. In another embodiment of the inventive concept, a pixel PX may be implemented in various configurations for emitting light in a light emitting element EE. The pixel circuit CC is illustrated on the basis of PMOS in FIG. 4 but is not limited thereto. In another embodiment of the inventive concept, a pixel circuit CC may be constituted on the basis of NMOS. In another embodiment of the inventive concept, a pixel circuit CC may be constituted of a combination of NMOS and PMOS.

Referring back to FIG. 3, a power supply pattern VDD is disposed in the non-display area NDA. In an embodiment, the power supply pattern VDD is connected to the plurality of power lines PL. Accordingly, the display panel DP may provide the same first power signal to the plurality of pixels PX by including the power supply pattern VDD.

The display pads PDD may include a first pad D1 and a second pad D2. The first pad D1 may be provided in plural, and the first pads D1 may be respectively connected to the data lines DL. The second pad D2 may be connected to the power supply pattern VDD to be electrically connected to the power line PL. The display panel DP may provide the pixels PX with electrical signals provided from the outside through the display pads PDD. In an embodiment, the display pads PDD may further include, in addition to the first pad D1 and the second pad D2, pads for receiving other electrical signals, and are not limited to any particular embodiment.

Referring to FIG. 5, an input sensing panel ISL may be disposed on the display panel DP. The input sensing panel ISL may be bonded to the display panel DP through a separate adhesive layer. However, the input sensing panel ISL is not limited thereto. The input sensing panel ISL may be directly formed on the display panel DP by a continuous process and is not limited to any particular embodiment.

The input sensing panel ISL may include a first sensing electrode TE1, a second sensing electrode TE2, a plurality of trace lines TL1, TL2, and TL3, and a plurality of sensing pads TP1, TP2, and TP3. A sensing area SA and a non-sensing area NSA may be defined in the input sensing panel ISL. In an embodiment, the non-sensing area NSA may surround the sensing area SA. The sensing area SA may be a sensing area for sensing an input applied from the outside. The sensing area SA may overlap the display area DA of the display panel DP.

The input sensing panel ISL may sense an external input in any of a self-capacitance type method and a mutual capacitance type method. The first sensing electrode TE1 and the second sensing electrode TE2 may be variously transformed according to the method and may be disposed and connected.

The first sensing electrode TE1 may include first sensing patterns SP1 and first bridge patterns BP1. The first sensing electrodes TE1 may each extend in the first direction DR1 and may be arranged in the second direction DR2. The first sensing patterns SP1 may be arranged to be spaced apart in the first direction DR1. At least one first bridge pattern BP1 may be disposed between two first sensing patterns SP1 adjacent to each other.

The second sensing electrode TE2 may include second sensing patterns SP2 and second bridge patterns BP2. The second sensing electrodes TE2 may each extend in the second direction DR2 and may be arranged in the first direction DR1. The second sensing patterns SP2 may be arranged to be spaced apart in the second direction DR2. At least one second bridge pattern BP2 may be disposed between two second sensing patterns SP2 adjacent to each other.

The trace lines TL1, TL2, and TL3 are disposed in the non-sensing area NSA. The trace lines TL1, TL2, and TL3 may include a first trace line TL1, a second trace line TL2, and a third trace line TL3.

The first trace line TL1 is connected to one end of the first sensing electrode TE1. The second trace line TL2 is connected to one end of the second sensing electrode TE2. The third trace line TL3 is connected to the other end of the second sensing electrode TE2. The other end of the second sensing electrode TE2 may be a portion opposing the one end of the second sensing electrode TE2.

According to an embodiment of the inventive concept, the second sensing electrode TE2 may be connected to the second trace line TL2 and the third trace line TL3. Accordingly, sensitivity according to the position along the second sensing electrode TE2 may be uniformly or substantially uniformly maintained for the second sensing electrode TE2 having a longer length than the first sensing electrode TE1. However, this is illustrated as an example, and the third trace line TL3 may be omitted and is not limited to any particular embodiment.

The sensing pads TP1, TP2, and TP3 are disposed in the non-sensing area NSA. The sensing pads TP1, TP2, and TP3 may include a first sensing pad TP1, a second sensing pad TP2, and a third sensing pad TP3. Each of the first sensing pad TP1, the second sensing pad TP2, and the third sensing pad TP3 may be provided in plural. The first sensing pads TP1 are respectively connected to the first trace lines TL1 and are electrically connected to the first sensing electrodes TE1, respectively. The second sensing pads TP2 are respectively connected to the second trace lines TL2, and the third sensing pads TP3 are respectively connected to the third trace lines TL3. Accordingly, one of the second sensing pads TP2 and a corresponding one of the third sensing pads TP3 are electrically connected to a corresponding one of the second sensing electrodes TE2.

FIG. 6 is a cross-sectional view of an electronic device according to an embodiment of the inventive concept. The same or similar reference numerals are used for components which are the same as or similar to the components described with reference to FIGS. 1A to 5, and a duplicate description will not be given. FIG. 6 illustrates only the display panel DP, the input sensing panel ISL, and the optical member OM among the components of the electronic device described with reference to FIGS. 2A to 2C.

Referring to FIG. 6, the display panel DP according to an embodiment of the inventive concept may include a base substrate BS, a plurality of insulating layers 10, 20, 30, 40, 50, and 60, and the pixels PX.

The base substrate BS may be optically transparent and may have insulating properties. For example, the base substrate BS may include a multilayer structure including glass, plastic, a polymer film, or an organic film and an inorganic film.

The insulating layers 10, 20, 30, 40, 50, and 60 may include first to sixth insulating layers 10, 20, 30, 40, 50, and 60 laminated on the base substrate BS. Each of the first to sixth insulating layers 10, 20, 30, 40, 50, and 60 may be an organic film or an inorganic film. In an embodiment, the display panel DP may further include an additional insulating layer in addition to the six insulating layers and is not limited to any particular embodiment.

Each of the pixels PX includes the light emitting element EE and a thin film transistor TR. The thin film transistor TR may include a semiconductor pattern SP and a control electrode CE. The semiconductor pattern SP is disposed between the first insulating layer 10 and the second insulating layer 20.

The semiconductor pattern SP may include a channel part S1, an input part S2, and an output part S3. The channel part S1, the input part S2, and the output part S3 may be parts divided in a plan view of the semiconductor pattern SP. The channel part S1 may have a lower conductivity than the input part S2 and the output part S3.

In an embodiment, the input part S2 and the output part S3 may include a reduced metal. The input part S2 and the output part S3 may respectively function as a source electrode and a drain electrode of the thin film transistor TR. However, the description above is given as an example, and the thin film transistor TR may further include separate source and drain electrodes in contact with the input part S2 and the output part S3, respectively, and the present disclosure is not limited to any particular embodiment.

The control electrode CE has conductivity. The control electrode CE is spaced apart from the semiconductor pattern SP with the second insulating layer 20 therebetween. The control electrode CE overlaps the channel part S1 of the semiconductor pattern SP when viewed in a plane.

The light emitting element EE is disposed on the thin film transistor TR. In an embodiment, the light emitting element EE is disposed on the fourth insulating layer 40 and is connected to the thin film transistor TR through a connection electrode BE separately provided. The connection electrode BE may penetrate the second insulating layer 20 and the third insulating layer 30 to be connected to the output part S3 of the thin film transistor TR, and the light emitting element EE may penetrate the fourth insulating layer 40 to be connected to the connection electrode BE.

However, this is illustrated as an example, and, in the display panel DP according to an embodiment of the inventive concept, the connection electrode BE may be disposed at another position or omitted, and is not limited to any particular embodiment.

The light emitting element EE includes a first electrode AN, a second electrode CT, a light emitting pattern EM, and a control layer CCL. The first electrode AN is disposed between the fourth insulating layer 40 and the fifth insulating layer 50. At least a portion of the first electrode AN is exposed by an opening D-OP defined in the fifth insulating layer 50.

The light emitting pattern EM is disposed in the opening D-OP and overlaps the exposed first electrode AN. The light emitting pattern EM may include a low molecular organic light emitting material or a high molecular organic light emitting material and may have fluorescence or phosphorescence characteristics. In another embodiment, the light emitting pattern EM may include an inorganic light emitting material, such as any of a quantum dot, a nano rod, a micro LED, and a nano LED. The light emitting element EE according to an embodiment of the inventive concept may include any of various light emitting materials as long as the light emitting materials are capable of generating light, and the light emitting element EE is not limited to any particular embodiment.

The second electrode CT may be disposed on the light emitting pattern EM and may be opposing the first electrode AN. The second electrode CT may be formed in an integral shape in the plurality of pixels PX. However, the description above is provided as an example, and the second electrode CT may be patterned and formed, in a shape similar to that of the first electrode AN, for each light emitting element EE and is not limited to any particular embodiment.

The control layer CCL is disposed between the first electrode AN and the light emitting pattern EM. The control layer CCL may include a hole injection region (or a hole injection layer) and a hole transport region (or a hole transport layer). In an embodiment, the control layer CCL may include the hole injection layer and the hole transport layer, and, in an embodiment, the hole injection layer may be omitted.

Although not illustrated, a charge control layer disposed between the light emitting pattern EM and the second electrode CT may be further included. The charge control layer may include a charge injection region (or an electron injection layer) and a charge transport region (or an electron transport layer).

The sixth insulating layer 60 may be disposed on the fifth insulating layer 50. The sixth insulating layer 60 may be an encapsulation layer. The sixth insulating layer 60 may include a first inorganic layer 61, an organic layer 62, and a second inorganic layer 63. However, the sixth insulating layer 60 is not limited thereto and may further include a plurality of inorganic layers and organic layers.

The first inorganic layer 61 may cover the second electrode CT. The first inorganic layer 61 may prevent or substantially prevent external moisture or oxygen from permeating into the light emitting element EE. For example, the first inorganic layer 61 may include silicon nitride, silicon oxide, or a compound thereof. In an embodiment, the first inorganic layer 61 may be formed through a deposition process.

The organic layer 62 may be disposed on the first inorganic layer 61 and may come in contact with the first inorganic layer 61. The organic layer 62 may provide a flat surface on the first inorganic layer 61. The organic layer 62 covers curvature formed on a top surface of the first inorganic layer 61, particles present on the first inorganic layer 61, or the like, and, thus, the surface condition of the top surface of the first inorganic layer 61 may be blocked from affecting components formed on the organic layer 62.

The organic layer 62 may include an organic material and may be formed through a solution process such as any of spin coating, slit coating, and an inkjet process.

The second inorganic layer 63 is disposed on the organic layer 62 to cover the organic layer 62. The second inorganic layer 63 may be stably formed on a flatter surface than when disposed on the first inorganic layer 61. The second inorganic layer 63 encapsulates moisture or the like emitted from the organic layer 62 and prevents or substantially prevents the moisture or the like from being introduced to the outside. The second inorganic layer 63 may include silicon nitride, silicon oxide, or a compound thereof. In an embodiment, the second inorganic layer 63 may be formed through a deposition process.

The input sensing panel ISL may be disposed on the sixth insulating layer 60. The input sensing panel ISL may include a plurality of conductive patterns TM1 and TM2 and a seventh insulating layer 70. The seventh insulating layer 70 may include a first sensing insulating layer 71, a second sensing insulating layer 72, and a third sensing insulating layer 73.

In an embodiment, the first sensing insulating layer 71 may be directly disposed on the second inorganic layer 63. A first conductive pattern TM1 is disposed on the first sensing insulating layer 71. The second sensing insulating layer 72 may be disposed on the first sensing insulating layer 71 to cover the first conductive pattern TM1. A second conductive pattern TM2 may be disposed on the second sensing insulating layer 72. The third sensing insulating layer 73 may be disposed on the second sensing insulating layer 72 to cover the second conductive pattern TM2. Each of the conductive patterns TM1 and TM2 has conductivity.

The conductive patterns TM1 and TM2 may constitute the sensing electrodes TE1 and TE2 described with reference to FIG. 5. For example, the first conductive pattern TM1 may constitute the first bridge patterns BP1 of the first sensing electrode TE1. The second conductive pattern TM2 may constitute the first sensing patterns SP1 of the first sensing electrode TE1, and the second sensing patterns SP2 and the second bridge patterns BP2 of the second sensing electrode TE2.

In an embodiment, the first sensing patterns SP1 of the first sensing electrode TE1, and the second sensing patterns SP2 and the second bridge patterns BP2 of the second sensing electrode TE2 constituted by the second conductive pattern TM2 may be provided as mesh lines.

The optical member OM according to an embodiment of the inventive concept may include the light blocking layer BM, the plurality of color filters CF-1, CF-2, and CF-3, and a planarization layer OL.

The light blocking layer BM may be disposed on the input sensing panel ISL. The light blocking layer BM may prevent or substantially prevent color mixing between the pixels PX providing light of different colors. The light blocking layer BM is not limited to any particular material as long as the material is capable of absorbing light.

The light blocking layer BM may be penetrated and may include a plurality of light emitting openings F-OP1 and F-OP2 defined by side surfaces of the light blocking layer BM. Surface areas of the light emitting openings F-OP1 and F-OP2 may be different from each other.

First light emitting openings F-OP1 may be defined by first side surfaces B-S1 of portions of the light blocking layer BM respectively overlapping a pixel providing red light and a pixel providing green light. A second light emitting opening F-OP2 may be defined by second side surfaces B-S2 of a portion of the light blocking layer BM overlapping a pixel providing blue light.

In an embodiment, a first surface area WA1 of one of the first light emitting openings F-OP1 of the light blocking layer BM overlapping the pixel providing red light may be the same as a second surface area WA2 of the other of the first light emitting openings F-OP1 of the light blocking layer BM overlapping the pixel providing green light.

According to an embodiment, a third surface area WA3 of the second light emitting opening F-OP2 of the light blocking layer BM overlapping the pixel providing blue light may be smaller than each of the first surface area WA1 and the second surface area WA2. Accordingly, in a cross-section, a first width W1 between corresponding ones of the first side surfaces B-S1 defining one of the first light emitting openings F-OP1 may be larger than a second width W2 between the second side surfaces B-S2 of the light blocking layer BM defining the second light emitting opening F-OP2.

Accordingly, among light provided from the pixels PX, an amount of light emitted through one of the first light emitting openings F-OP1 may be greater than an amount of light emitted through the second light emitting opening F-OP2.

In an embodiment, a pixel providing red light may be defined as a first pixel, a pixel providing green light may be defined as a second pixel, and a pixel providing blue light may be defined as a third pixel. In this case, a width of a portion of the light blocking layer BM disposed between the second and third pixels may be larger than a width of a portion of the light blocking layer BM disposed between the first and second pixels.

In an embodiment, an increased width IP1 may be, in a cross-section, about 20% to about 30% of the width of the portion of the light blocking layer BM disposed between the first and second pixels. When the increased width IP1 is less than about 20% thereof, there may be no or substantially no difference between the amounts of light emitted from one of the first light emitting openings F-OP1 and the second light emitting opening F-OP2, and when the increased width IP1 is larger than about 30% thereof, most of light provided from the third pixel may be absorbed by the light blocking layer BM, and, thus, light loss may occur.

According to an embodiment, the surface area of the second light emitting opening F-OP2 of the light blocking layer BM overlapping the pixel providing blue light is smaller than the surface area of any of the first light emitting openings F-OP1 respectively overlapping the pixel providing red light and the pixel providing green light, such that luminance of the blue light may be directly reduced at a tilted angle. Accordingly, an electronic device EA having improved color purity may be provided.

The optical member OM according to an embodiment may include the plurality of color filters CF-1, CF-2, and CF-3. A first color filter CF-1 may be disposed on the pixel providing red light to overlap one of the first light emitting openings F-OP1, and a second color filter CF-2 may be disposed on the pixel providing green light to overlap the other of the first light emitting openings F-OP1. A third color filter CF-3 may be disposed on the pixel providing blue light to overlap the second light emitting opening F-OP2.

In an embodiment, the first color filter CF-1 may transmit red light, the second color filter CF-2 may transmit green light, and the third color filter CF-3 may transmit blue light. In an embodiment, each of the color filters CF-1, CF-2, and CF-3 may include polymer photosensitive resin and a pigment or dye.

The planarization layer OL may cover the color filters CF-1, CF-2, and CF-3. The planarization layer OL may be disposed on the color filters CF-1, CF-2, and CF-3 to cover irregularities generated in the process of forming the color filters CF-1, CF-2, and CF-3. Accordingly, a component disposed on the optical member OM may be stably coupled to the optical member OM.

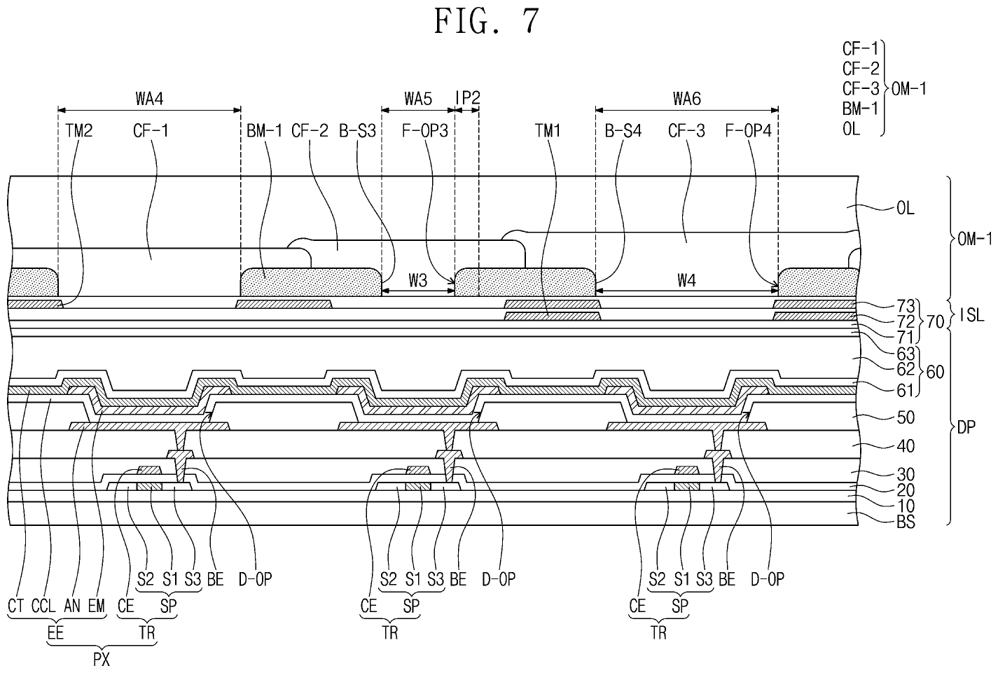

FIG. 7 is a cross-sectional view of an electronic device according to an embodiment of the inventive concept. The same or similar reference numerals are used for components which are the same as or similar to the components described with reference to FIGS. 1A to 6, and a duplicate description will not be given.

An optical member OM-1 according to an embodiment of the inventive concept may include a light blocking layer BM-1, a plurality of color filters CF-1, CF-2, and CF-3, and a planarization layer OL.

The light blocking layer BM-1 may be disposed on an input sensing panel ISL. The light blocking layer BM-1 may prevent or substantially prevent color mixing between pixels PX providing light of different colors. The light blocking layer BM-1 is not limited to any particular material as long as the material is capable of absorbing light.

The light blocking layer BM-1 may be penetrated and may include a plurality of light emitting openings F-OP3 and F-OP4 defined by side surfaces of the light blocking layer BM-1. Surface areas of the light emitting openings F-OP3 and F-OP4 may be different from each other.

A third light emitting opening F-OP3 may be defined by third side surfaces B-S3 of a portion of the light blocking layer BM-1 overlapping a pixel providing green light. Fourth light emitting openings F-OP4 may be defined by fourth side surfaces B-S4 of portions of the light blocking layer BM-1 respectively overlapping a pixel providing red light and a pixel providing blue light.

In an embodiment, a fifth surface area WA5 of the third light emitting opening F-OP3 of the light blocking layer BM-1 overlapping the pixel providing green light may be smaller than a fourth surface area WA4 of any of the fourth light emitting openings F-OP4 of the light blocking layer BM-1 respectively overlapping the pixel providing red light and the pixel providing blue light.

Accordingly, in a cross-section, a third width W3 between the third side surfaces B-S3 defining the third light emitting opening F-OP3 may be smaller than a fourth width W4 between corresponding ones of the fourth side surfaces B-S4 of the light blocking layer BM-1 defining one of the fourth light emitting openings F-OP4.

Accordingly, among light provided from pixels PX, an amount of light emitted through one of the fourth light emitting openings F-OP4 may be greater than an amount of light emitted through the third light emitting opening F-OP3.

In an embodiment, a pixel providing red light may be defined as a first pixel, a pixel providing green light may be defined as a second pixel, and a pixel providing blue light may be defined as a third pixel. Light provided from the first to third pixels may be mixed to provide white light. In an embodiment, a ratio of the green light to the white light may be about 50% or more.

In this case, a width of a portion of the light blocking layer BM-1 disposed between the first and second pixels and between the second and third pixels may be greater than a width of a portion of the light blocking layer BM-1 disposed between the first and third pixels.

In an embodiment, an increased width IP2 may be, in a cross-section, about 20% to about 30% of the width of the portion of the light blocking layer BM-1 disposed between the first and third pixels. When the increased width IP2 is less than about 20%, there may be no or substantially no difference between the amounts of light emitted from the third light emitting opening F-OP3 and one of the fourth light emitting openings F-OP4, and when the increased width IP2 is larger than about 30%, most of light provided from the second pixel may be absorbed by the light blocking layer BM-1, and, thus, light loss may occur.

According to an embodiment, the surface area of the third light emitting opening F-OP3 of the light blocking layer BM-1 overlapping the pixel providing green light may be smaller than the surface area of any of the fourth light emitting openings F-OP4 respectively overlapping the pixel providing red light and the pixel providing blue light, such that an amount of the green light among an amount of the white light may be reduced. Accordingly, an electronic device EA having improved color purity at a tilted angle may be provided.

According to one or more embodiments, among the light emitting openings defined in the light blocking layer, the light emitting opening overlapping the pixel providing blue light has a smaller surface area than any one of the light emitting openings respectively overlapping the pixel providing red light and the pixel providing green light, such that luminance of the blue light may be directly reduced at a tilted angle. Accordingly, an electronic device having improved color purity may be provided.

Although some embodiments of the inventive concept have been described herein, it is to be understood that various changes and modifications can be made by those skilled in the art within the spirit and scope of the inventive concept as set forth by the following claims and equivalents thereof.

Accordingly, the embodiments described herein are not intended to limit the technical spirit and scope of the present invention, and all technical spirit within the scope of the following claims or equivalents thereof is to be construed as being included in the scope of the present invention.

What is claimed is:

1. An electronic device comprising:
an optical member comprising a light blocking layer including a first light emitting opening and a second light emitting opening each defined by adjacent side surfaces, a first color filter overlapping the first light emitting opening, and a second color filter overlapping the second light emitting opening; and
a display panel comprising a first pixel configured to provide the first light emitting opening with light of a first color, and a second pixel configured to provide the second light emitting opening with light of a second color different from the light of the first color,
wherein a surface area of the first light emitting opening is different from a surface area of the second light emitting opening.

2. The electronic device of claim 1, wherein
the first light emitting opening is defined by first side surfaces of a portion of the light blocking layer overlapping the first pixel, and
the second light emitting opening is defined by second side surfaces of a portion of the light blocking layer overlapping the second pixel,
wherein a width between the first side surfaces is, in a cross-section, smaller than a width between the second side surfaces.

3. The electronic device of claim 2, wherein
the light of the first color is blue light, and
the light of the second color is any of green light and red light.

4. The electronic device of claim 3, wherein an amount of the light of the first color passing through the first light emitting opening is less than an amount of the light of the second color passing through the second light emitting opening.

5. The electronic device of claim 2, wherein
the light of the first color is any of green light and red light, and
the light of the second color is blue light.

6. The electronic device of claim 1, wherein
the optical member further comprises a third light emitting opening defined in the light blocking layer, and a third color filter overlapping the third light emitting opening, and
the display panel further comprises a third pixel configured to provide light of a third color different from the light of the first color and the light of the second color.

7. The electronic device of claim 6, wherein a surface area of the third light emitting opening is the same as the surface area of the second light emitting opening and is larger than the surface area of the first light emitting opening.

8. The electronic device of claim 7, wherein a first width of a portion of the light blocking layer arranged between the second pixel and the third pixel is, in a cross-section, smaller than a second width of a portion of the light blocking layer arranged between the first pixel and the second pixel.

9. The electronic device of claim 8, wherein the second width is about 20% to about 30% greater than the first width.

10. The electronic device of claim 1, further comprising an input sensing panel configured to sense an external input and arranged between the display panel and the optical member.

11. The electronic device of claim 10, wherein the input sensing panel comprises a plurality of sensing insulating layers and conductive patterns arranged between the insulating layers,
wherein at least one of the conductive patterns is configured as mesh lines.

12. The electronic device of claim 10, wherein the input sensing panel is directly arranged on the display panel.

13. The electronic device of claim 1, further comprising:
a window on the optical member; and
an adhesive layer configured to bond the window to the optical member.

14. The electronic device of claim 1, further comprising a protection member on a lower portion of the display panel,
wherein the protection member comprises any of a light blocking pattern, a heat dissipation layer, and a cushion layer.

15. The electronic device of claim 1, wherein the display panel comprises a folding area that is foldable about an imaginary folding axis extending in a first direction, and non-folding areas spaced apart from each other in a direction crossing the first direction with the folding area therebetween.

16. An electronic device comprising:
an optical member comprising a light blocking layer including first to third light emitting openings, and first to third color filters each overlapping a corresponding light emitting opening of the first to third light emitting openings; and
a display panel comprising first to third pixels each configured to provide light to a corresponding light emitting opening of the first to third light emitting openings,
wherein a width between side surfaces of the light blocking layer defining the first light emitting opening is different from a width between side surfaces of the light blocking layer defining each of the second and third light emitting openings.

17. The electronic device of claim 16, wherein the first pixel overlapping the first light emitting opening is configured to provide blue light.

18. The electronic device of claim 16, wherein a surface area of the first light emitting opening is smaller than a surface area of each of the second and third light emitting openings.

19. The electronic device of claim 16, wherein a first width of a portion of the light blocking layer arranged between the second pixel and the third pixel is, in a cross-section, smaller than a second width of a portion of the light blocking layer arranged between the first pixel and the second pixel.

20. The electronic device of claim 19, wherein the second width is about 20% to about 30% greater than the first width.
